(19) United States
(12) Patent Application Publication
(10) Pub. No.: US 2025/0362586 A1
(43) Pub. Date: Nov. 27, 2025

(54) SUPPORTING FRAME AND MASK ASSEMBLY INCLUDING SAME

(71) Applicants: Samsung Display Co., LTD., Yongin-si (KR); Pusan National University Industry-University Cooperation Foundation, Busan (KR)

(72) Inventors: Mina WOO, Yongin-si (KR); Jeong KIM, Busan (KR); Ujin SONG, Busan (KR); JONGBUM KIM, Yongin-si (KR); Yeonbok KIM, Busan (KR); Byeongjin PARK, Busan (KR); Jiye PARK, Busan (KR)

(21) Appl. No.: 19/018,065

(22) Filed: Jan. 13, 2025

(30) Foreign Application Priority Data
May 24, 2024 (KR) 10-2024-0067945

(51) Int. Cl. G03F 1/64; H10K 71/16

(52) U.S. Cl. CPC G03F 1/64; H10K 71/166

(57) ABSTRACT

A supporting frame according to an embodiment includes a body part including a first frame part, a second frame part, a third frame part, and a fourth frame part disposed on a first side, a second side, a third side, and a fourth side of an opening, respectively, and a supporting bar coupled to the first frame part. The supporting bar has a shape convex toward an outside of the supporting frame.

This application claims priority to Korean Patent Application No. 10-2024-0067945, filed on May 24, 2024, and all the benefits accruing therefrom under 35 U.S.C. § 119, the content of which in its entirety is herein incorporated by reference.

### BACKGROUND OF THE DISCLOSURE

### 1. Field of the Disclosure

The present disclosure relates to a supporting frame and a mask assembly including the supporting frame.

### 2. Description of the Related Art

In order to manufacture an organic light emitting display device, an electrode and an organic emission layer with a specific pattern may be formed, and a deposition process using a mask assembly may be applied as a method of forming the electrode and the organic emission later, and accordingly, the organic light emitting display device. The mask assembly may include a plurality of unit masks formed with an opening of a pattern such as, for example, a metal layer or an organic emission layer to be deposited, a frame supporting the plurality of unit masks, and a stick. The unit mask and the stick may be affixed to the frame with a tension applied in the length direction.

The frame may be exposed to heat during the deposition process using the mask assembly. In some aspects, the deposition process using the mask assembly may be carried out with the frame erected horizontally or vertically.

### SUMMARY OF THE DISCLOSURE

Embodiments are intended to provide a supporting frame and a mask assembly including the supporting frame in which a deformation caused by the supporting frame's self-weight and a tensile force applied to the stick is offset.

A supporting frame according to an embodiment includes a body part including a first frame part, a second frame part, a third frame part, and a fourth frame part disposed on a first side, a second side, a third side, and a fourth side of an opening, respectively, and a supporting bar coupled to the first frame part, wherein the supporting bar has a shape convex toward an outside of the supporting frame.

In a state in which the supporting frame is erected vertically, the first frame part may be positioned on an upper side of the opening.

The supporting bar may be formed such that the supporting bar has a first curvature, and the supporting bar may be transformable and joinable to the first frame part based on an external force, wherein in response to the external force, the supporting bar may have a second curvature less than the first curvature and be joined to the first frame part.

The body part may include a first material, the supporting bar may include a second material, and a thermal expansion coefficient of the second material may be larger than a thermal expansion coefficient of the first material.

The second material may weigh less than the first material.

An outer surface of the first frame part may include a groove that is recessed toward an inner surface of the first frame part, a bottom surface of the groove may be convex toward an outside of the supporting frame, and the supporting bar may be inserted into the groove.

The outer surface of the first frame part and the inner surface of the supporting bar may each include alternating protrusions and depressions, and the protrusions of the outer surface of the first frame part may be configured to interlock with the depressions of the inner surface of the supporting bar, and the depressions of the outer surface of the first frame part may be configured to interlock with the protrusions of the inner surface of the supporting.

The body part may include a front surface and a rear surface facing in a direction where the opening penetrates the supporting frame, a rear surface of the first frame part may include a groove that is recessed toward a front surface of the first frame part, wherein the groove may have a shape convex toward the outside of the supporting frame, and the supporting bar may be inserted into the groove.

The body part may include a first body part and a second body part that are joined in a thickness direction of the supporting frame, the first body part and the second body part may each include a respective first frame part, a respective second frame part, a respective third frame part, and a respective fourth frame part; the first surface of the first frame part of the first body part, which is joined to the first frame part of the second body part, may include a groove recessed toward the opposite side of the first surface, and the groove has a shape that is convex toward the outside of the supporting frame, the supporting bar may be inserted into the groove, and an entrance of the groove may be blocked by a second surface of the first frame part of the second body part, which is joined to the first frame part of the first body part.

The first surface of the first frame part of the first body part may include a first groove that is recessed toward the opposite side of the first surface, the second surface of the first frame part of the second body part may include a second groove recessed toward the opposite side of the second surface, the first groove and the second groove may each have a shape convex toward the outside of the supporting frame, a part of the supporting bar may be inserted into the first groove, and a remaining part of the supporting bar may be inserted into the second groove.

A mask assembly according to an embodiment includes a supporting frame including a body part surrounding a first opening and a supporting bar coupled to the body part, a first stick disposed on the supporting frame and extending in a first direction, a second stick disposed on the supporting frame and extending in a second direction perpendicular to the first direction, and a unit mask disposed on the supporting frame, the first stick, and the second stick, and including one or more second openings, wherein the body part includes a first frame part, a second frame part, a third frame part, and a fourth frame part disposed on a first side, a second side, a third side, and a fourth side of the first opening, respectively, the supporting bar is coupled to the first frame part, and the supporting bar has a shape convex toward the outside of the supporting frame.

In a state in which the supporting frame is erected vertically, the first frame part may be positioned on the upper side of the first opening.

The supporting bar may be formed such that the supporting bar has a first curvature, and the supporting bar may be transformable and joinable to the first frame part based on an external force, wherein in response to the external force, the supporting bar may have a second curvature less than the first curvature and be joined to the first frame part.

The body part may include a first material, the supporting bar may include a second material, and a thermal expansion coefficient of the second material may be larger than a thermal expansion coefficient of the first material.

The second material may weigh less than the first material.

An outer surface of the first frame part may include a groove that is recessed toward an inner surface of the first frame part, a bottom surface of the groove may be convex toward an outside of the supporting frame, and the supporting bar may be inserted into the groove.

The outer surface of the first frame part and the inner surface of the supporting bar may each include alternating protrusions and depressions, and the protrusions of the outer surface of the first frame part may be configured to interlock with the depressions of the inner surface of the supporting bar, and the depressions of the outer surface of the first frame part may be configured to interlock with the protrusions of the inner surface of the supporting bar.

The body part may include a front surface to which the unit mask is affixed and a rear surface opposite to the front surface, a rear surface of the first frame part may include a groove that is recessed toward a front surface of the first frame part, wherein the groove may have a shape convex toward the outside of the supporting frame, and the supporting bar may be inserted into the groove.

The body part may include a first body part and a second body part that are joined in a thickness direction of the supporting frame, the first body part and the second body part may each include a respective first frame part, a respective second frame part, a respective third frame part, and a respective fourth frame part; a first surface of the first frame part of the first body part, which is joined to the first frame part of the second body part, may include a groove recessed toward an opposite side of the first surface, and the groove may have a shape that is convex toward the outside of the supporting frame, and the supporting bar may be inserted into the groove, and an entrance of the groove may be blocked by a second surface of the first frame part of the second body part, which is joined to the first frame part of the first body part.

The first surface of the first frame part of the first body part may include a first groove recessed toward the opposite side of the first surface, the second surface of the first frame part of the second body part may include a second groove recessed toward the opposite side of the second surface, the first groove and the second groove may each have a shape convex toward the outside of the supporting frame, a part of the supporting bar may be inserted into the first groove, and a remaining part of the supporting bar may be inserted into the second groove.

According to embodiments, the deformation caused by the self-weight of the supporting frame and the tensile force applied to the stick may be offset.

### BRIEF DESCRIPTION OF THE DRAWINGS

FIG. 1 is an exploded perspective view of a mask assembly according to an embodiment.

FIG. 2 is an exploded perspective view of a supporting frame according to an embodiment.

FIG. 3 is a cross-sectional view of a supporting bar according to an embodiment.

FIG. 4 is a view to compare a supporting frame according to various embodiments with a supporting frame according to a comparative example.

FIG. 5 is a view to compare a supporting frame according to an embodiment with a supporting frame according to a comparative example.

FIG. 6 to FIG. 8 are exploded perspective views of a supporting frame according to an embodiment.

### DETAILED DESCRIPTION

The present disclosure will be described more fully hereinafter with reference to the accompanying drawings, in which example embodiments of the disclosure are illustrated. As those skilled in the art would realize, the described embodiments may be modified in various different ways, all without departing from the spirit or scope of the present disclosure.

To make the description clear, parts unrelated to the description of the example embodiments are not illustrated, and like reference numerals designate like elements throughout the specification.

The size and thickness of the configurations are optionally illustrated in the drawings for convenience of description, and the present disclosure is not limited to the drawings. In the drawings, the thickness of layers, films, panels, regions, other elements, and the like, are exaggerated for clarity. In the drawings, for better understanding and ease of description, the thicknesses of some layers and areas are exaggerated.

It should be understood that when an element such as, for example, a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Unless explicitly stated to the contrary, the word “comprise,” and variations such as, for example, “comprises” or “comprising,” should be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

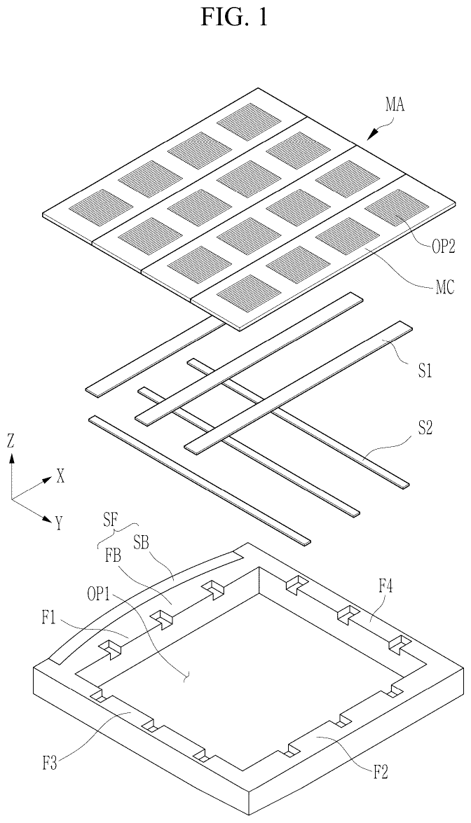

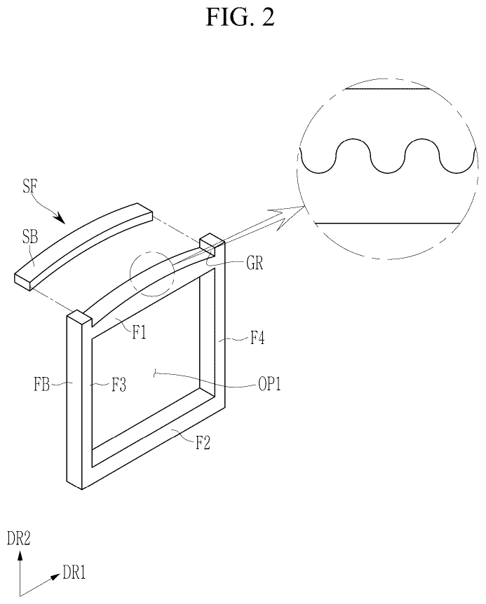

Hereinafter, a supporting frame and a mask assembly including the supporting frame according to an embodiment are described with reference to FIG. 1 and FIG. 2.

FIG. 1 is an exploded perspective view of a mask assembly according to an embodiment, and FIG. 2 is an exploded perspective view of a supporting frame according to an embodiment.

Referring to FIG. 1, a mask assembly MA according to an embodiment may include a supporting frame SF, a first stick S1 and a second stick S2 disposed on the supporting frame SF, and a unit mask MC disposed on the supporting frame SF, the first stick S1, and the second stick S2.

According to an embodiment, the supporting frame SF may include a body part FB and a supporting bar SB coupled to the body part FB. The body part FB may include a first frame part F1, a second frame part F2, a third frame part F3, and a fourth frame part F4, respectively disposed on the first side, the second side, the third side, and the fourth side of a first opening OP1.

The first frame part F1 and the second frame part F2 may extend in a first direction and be separated in a second direction Y vertical to the first direction X. The third frame part F3 and the fourth frame part F4 may extend in the second direction Y and may be spaced apart in the first direction X. The third frame part F3 may connect one end of the first frame part F1 and one end of the second frame part F2, and the fourth frame part F4 may connect the other end of the first frame part F1 and the other end of the second frame part F2. The first frame part F1 may connect one end of the third frame part F3 and the other end of the fourth frame part F4, and the second frame part F2 may connect the other end of the third frame part F3 and the other end of the fourth frame part F4.

The first opening OP1 may penetrate the supporting frame SF in a third direction Z vertical to the first direction X and the second direction Y. The first opening OP1 may be surrounded by the first frame part F1, the second frame part F2, the third frame part F3, and the fourth frame part F4.

According to an embodiment, the supporting bar SB may be combined with the first frame part F1. Hereinafter, the supporting bar SB and the first frame part F1 are described with reference to FIG. 2.

The first stick S1 and the second stick S2 may be disposed across the first opening OP1. The first stick S1 may be extended in the first direction X. The second stick S2 may be extended in the second direction Y vertical to the first direction X. One or more first sticks S1 and second sticks S2 may each be provided. The plurality of first sticks S1 may be disposed to be spaced apart in the second direction Y vertical to the first direction X.

The plurality of second sticks S2 may be disposed apart from each other in the first direction X vertical to the second direction Y.

Both ends of each of the first stick S1 and the second stick S2 may be coupled to the supporting frame SF. For example, the body part FB of the supporting frame SF may include a groove that accommodates both ends of each of the first stick S1 and the second stick S2. The first stick S1 and the second stick S2 may be coupled to the supporting frame SF by inserting both ends of each of the first stick S1 and second stick S2 into the groove of the body part FB. The first stick S1 may be inserted into the grooves facing in the first direction among the grooves of the body part FB, and the second stick S2 may be inserted into the grooves facing in the second direction Y among the grooves of the body part FB. However, the method of combining first stick S1, the second stick S2, and the supporting frame SF is not limited to the examples described herein and can be changed in various ways. For example, the first stick S1 and the second stick S2 may be coupled to the supporting frame SF through an affixed member.

The first stick S1 and the second stick S2 may each be pulled in the length direction and coupled to the supporting frame SF. The first stick S1 may be pulled in the first direction X and coupled to the supporting frame SF. The second stick S2 may be pulled in the second direction Y and coupled to the supporting frame SF. Accordingly, a compressive force may be applied to the supporting frame SF in each of the tensile directions of the first stick S1 and the second stick S2, such as, for example, the first direction X and the second direction Y. The supporting frame SF may be formed of a material with a low deformation due to such compressive force—that is, a metal material with a high rigidity.

The unit mask MC may be disposed on the supporting frame SF, the first stick S1, and the second stick S2. The unit mask MC may be in the form of a stick or a band extending in the first direction X. The unit mask MC may be pulled in the first direction X and affixed to the supporting frame SF. For example, both ends of the unit mask MC may be affixed to the third frame part F3 and the fourth frame part F4, which are spaced apart in the first direction X, respectively.

The unit mask MC may include one or more second openings OP2. One or more second openings OP2 may be spaced apart in the first direction DR1 on the unit mask MC. The second opening OP2 may include an opening pattern corresponding to one organic light emitting display device. The opening pattern may have the form of an open pattern penetrating the unit mask MC. For example, the opening pattern may include a plurality of slits of a stripe type, but embodiments of the present disclosure are not limited thereto. In the deposition process using the mask assembly MA, the deposition material passes through the second opening OP2 and is deposited on the substrate to form a thin film (e.g., organic emission layer) with a pattern corresponding to the opening pattern of the second opening OP2.

The unit mask MC may be a fine metal mask (FMM) formed of a metal thin film. The unit mask MC may be formed of any one selected from a group consisting of stainless steel, invar, nickel, cobalt, and alloys thereof.

According to an embodiment, there may be a plurality of unit masks MC. The plurality of unit masks MC may be arranged side by side in the second direction Y vertical to the first direction X. The plurality of unit masks MC may be supported by the supporting frame SF, the first stick S1, and the second stick S2. The supporting frame SF may support both ends of each of the plurality of unit masks MC. The first stick S1 and the second stick S2 may support the middle portions between both ends of each of the plurality of unit masks MC.

The first stick S1 may support two adjacent unit masks MC. The first stick S1 be disposed across two adjacent unit masks MC. The first stick S1 may be disposed between the second openings OP2 arranged in the second direction Y of two adjacent unit masks MC.

The second stick S2 may support the plurality of unit masks MC. The second stick S2 may be disposed across the plurality of unit masks MC. The second stick S2 may be disposed between the second openings OP2 arranged in the first direction X of each of the plurality of unit masks MC.

The first stick S1 and the second stick S2 do not shield the second openings OP2 of the plurality of unit masks MC, but may be arranged such that the second openings OP2 are exposed toward the first opening OP1. The first stick S1 and the second stick S2 may partition the first opening OP1 into a plurality of regions. The plurality of regions of the first opening OP1 partitioned by the first stick S1 and the second stick S2 may overlap the second openings OP2 of the plurality of unit masks MC in the third direction Z, respectively.

An example embodiment may include using the mask assembly MA in the organic material deposition process during the process of manufacturing the organic light emitting display device, but embodiments of the present disclosure are not limited thereto. Each of the second openings OP2 of the unit mask MC may correspond to one organic light emitting display device. In the organic material deposition process using the mask assembly MA, the organic emission layer of each of the plurality of organic light emitting display devices may be formed simultaneously.

According to an embodiment, the supporting frame SF constitutes the mask assembly MA, and the mask assembly MA is explained as being used in the organic material deposition process, but embodiments of the present disclosure are not limited thereto. Hereinafter, the explanation of the supporting frame SF referred to in FIG. 2 may be applied equally or similarly to the frame structures for various purposes. Here, the frame structure as a closed-loop structure that includes an opening in the center may refer to a structure that includes a portion positioned above the opening when the frame structure is erected vertically on a support surface.

FIG. 2 is the drawing illustrating the state in which the supporting frame SF is erected in the third direction Z of FIG. 1. Referring to FIG. 2, when (i.e., in a state in which) the supporting frame SF is erected vertically on the supporting surface, the first frame part F1 may be positioned above the first opening OP1, and the second frame part F2 may be positioned below the first opening OP1. For example, the second frame part F2 may be in contact with the support surface.

The first frame part F1 and the second frame part F2 may extend in the first direction DR1, and may be spaced apart from each other in the second direction DR2 vertical to the first direction DR1. The third frame part F3 and the fourth frame part F4 may extend in the second direction DR2, and may be spaced apart in the first direction DR1. In FIG. 2, the first direction DR1 may be a direction parallel to the support surface, and the second direction DR2 may be a direction perpendicular to the support surface. The second direction DR2 may be a direction perpendicular to the first direction DR1.

Hereinafter, a direction toward the inside of the supporting frame SF may mean the direction toward the first opening OP1, and a direction toward the outside of the supporting frame SF may mean a direction opposite to the direction toward the first opening OP1.

The supporting bar SB may have a shape extending in the first direction DR1. The supporting bar SB may be combined on the outer surface of the first frame part F1. The supporting bar SB may have a convex shape to the outside of the supporting frame SF.

According to an embodiment, the outer surface of the first frame part F1 may include a groove GR that is recessed toward the inner surface of the first frame part F1. The supporting bar SB may be inserted into the groove GR. The bottom surface of the groove GR may be convex toward the outside of the supporting frame SF. Both ends of the supporting bar SB may be inserted into both sides of the groove GR.

The length along the first direction DR1 of the groove GR may be substantially the same as the length along the first direction DR1 of the supporting bar SB, but embodiments of the present disclosure are not limited thereto.

Referring to the enlarged view of the junction surface of the outer surface of the first frame part F1 and the inner surface of the supporting bar SB, the outer surface of the first frame part F1 and the inner surface of the supporting bar SB may include alternating protrusions (also referred to herein as protruding parts, protruding portions, or the like) and depressions (also referred to herein as concave parts, concave portions, or the like). The protruded parts and the concave parts may be arranged alternately on the outer surface of the first frame part F1 and the inner surface of the supporting bar SB, respectively. For example, both the protruded parts and the concave parts may have a round shape, but there is no limit to the shape of the protrusions and depressions, which may be changed in various ways. The protrusions and depressions of the outer surface of the first frame part F1 and the protrusions and depressions of the inner surface of the supporting bar SB may be interlocked. That is, the protruded part of the outer surface of the first frame part F1 may be inserted into the concave part of the inner surface of the supporting bar SB, and the protruded part of the inner surface of the supporting bar SB may be inserted into the concave part of the outer surface of the first frame part F1.

Accordingly, for example, the protrusions (protruding parts) of the outer surface of the first frame part are configured to interlock with the depressions (concave parts) of the inner surface of the supporting bar, and the depressions (concave parts) of the outer surface of the first frame part are configured to interlock with the protrusions (protruding parts) of the inner surface of the supporting bar.

As the temperature increases, the supporting frame SF may expand based on the thermal expansion coefficient of the material constituting the supporting frame SF, and the expansion may be referred to as a thermal distortion. In order to minimize the thermal distortion of the supporting frame SF, embodiments of the present disclosure may include using a material with a low thermal expansion coefficient as the material of the supporting frame SF. The material with a low thermal expansion coefficient may include, for example, Invar 36. Invar 36 is an alloy of nickel and iron including 36% nickel.

According to an embodiment, the supporting frame SF may be a structure in which the supporting bar SB is combined with the body part FB. The body part FB may include a first material, and the supporting bar SB may include a second material. According to an embodiment, the first material and the second material may be different materials, but is not limited thereto, and the first material and the second material may be the same material.

According to an embodiment, a thermal expansion coefficient of the second material may be larger than a thermal expansion coefficient of the first material. For example, the thermal expansion coefficient of the second material may be approximately 20 times the thermal expansion coefficient of the first material. For example, the first material may be Invar 36, and the second material may be aluminum. The supporting bar SB including the second material may be more prone to thermal distortion as the temperature increases compared to the body part FB including the first material. As the supporting bar SB has a convex shape as described herein toward the outside of the supporting frame SF, thermal distortion of the supporting bar SB may occur toward the outside of the supporting frame SF.

The first frame part F1 of the body part FB is disposed on the upper side of the first opening OP1 when (i.e., in a state in which) the supporting frame SF is erected vertically, and in some cases, the first frame part F1 may sag toward the inside of the supporting frame SF due to self-weight.

According to an embodiment, in the supporting frame SF, the sticks (e.g., the first stick S1 and the second stick S2 in FIG. 1) may be coupled to the supporting frame SF across the first opening OP1. For example, the stick may be coupled to the first frame part F1 and the second frame part F2, or to the third frame part F3 and the fourth frame part F4. The stick may be stretched in the length direction and coupled to the supporting frame SF, and a compressive force may be applied to the supporting frame SF along the stretching direction of the stick. The first frame part F1 may sag toward the inside of the supporting frame SF due to the compressive force caused by the stick.

According to the example aspects described herein, based on the shape of the supporting bar SB, the thermal distortion direction of the supporting bar SB may be toward the outside the supporting frame SF. In other words, the thermal distortion of the supporting bar SB may occur in a direction such that the thermal distortion offsets the deflection of the first frame part F1 to which the supporting bar SB is coupled.

According to an embodiment, as the temperature increases, the supporting bar SB may expand and be more tightly coupled to the first frame part F1. For example, as the supporting bar SB expands, both ends of the supporting bar SB may expand and come into closer contact with both sides of the groove GR. As the supporting bar SB expands, the protruded portion of the protrusions and depressions of the supporting bar SB may be brought into closer contact with the concave portion of the protrusions and depressions of the first frame part F1. As the supporting bar SB expands, the concave portion of the protrusions and depressions of the supporting bar SB may be brought into closer contact with the protruded portion of the protrusions and depressions of the first frame part F1.

According to an embodiment, the second material may weigh less than the first material. For example, the first material may be Invar 36 and the second material may be aluminum. In some cases, when (i.e., in a state in which) the supporting frame SF is erected vertically, the portion of the supporting frame SF disposed on the upper side of the first opening OP1 may sag toward the inside of the supporting frame SF due to self-weight. In an example in which the supporting frame SF is erected vertically, the first frame part F1 and the supporting bar SB coupled to the first frame part F1 may correspond to the portion of the supporting frame SF disposed on the upper side of the first opening OP1. By replacing the material of the supporting bar SB with a material lighter than the material of the first frame part F1, the amount of the sagging of the part of the supporting frame SF disposed on the upper side of the first opening OP1 may be reduced when (i.e., for cases in which) the supporting frame SF is erected vertically.

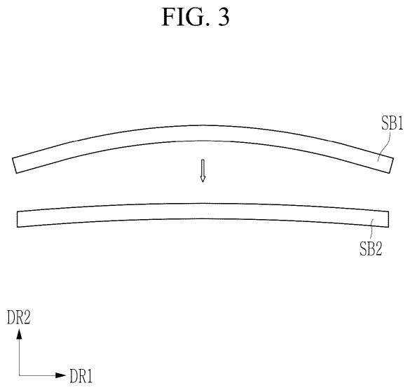

Hereinafter, the supporting bar of the supporting frame according to an embodiment will be described with reference to FIG. 3.

FIG. 3 is a cross-sectional view of a supporting bar SB according to an embodiment. The first supporting bar SB1 and the second supporting bar SB2 in FIG. 3 may represent the cross-section according to the first direction DR1 and the second direction DR2 of the supporting bar SB of FIG. 2, respectively.

Referring to FIG. 2 and FIG. 3 together, the first supporting bar SB1 may have a first curvature convex toward the outside of the supporting frame SF when combined with the first frame part F1. The second supporting bar SB2 illustrates an example modification (i.e., transformation) of the first supporting bar SB1 formed in response to applying an external force to the first supporting bar SB1. The second supporting bar SB2 may have a second curvature different from the first curvature. The second curvature may be a smaller curvature than the first curvature, when (i.e., in a state in which) the second supporting bar SB2 is coupled to the first frame part F1 and is convex toward the outside of the supporting frame SF. Here, the external force is applied before the second supporting bar SB2 is coupled to the first frame part F1, and the external force may be referred to as a prestress. That is, the first supporting bar SB1 may correspond to the initial shape of the supporting bar SB, and the second supporting bar SB2 may correspond to the shape after applying the prestress to the supporting bar SB.

According to an embodiment, the second supporting bar SB2, whose curvature has become smaller than the initial shape due to the application of the prestress, may be combined with the first frame part F1. The second supporting bar SB2, to which the prestress is applied, may have a restoring force supportive of returning the second supporting bar SB2 to the initial shape of the second supporting bar SB2 (e.g., in the absence of the prestress). In other words, the restoring force may act on the second supporting bar SB2 to cause the second supporting bar SB2 return from the second curvature to the first curvature. The restoring force may be in a direction toward the outside the supporting frame SF in the state that the second supporting bar SB2 is coupled to the first frame part F1. The direction of the restoring force may be opposite the direction in which the first frame part F1 sags when the supporting frame SF is erected vertically.

In a state where the second supporting bar SB2 is coupled to the first frame part F1, the restoring force of the second supporting bar SB2 may be transmitted to the first frame part F1. Due to the restoring force of the second supporting bar SB2, the sagging phenomenon of the first frame part F1 when the supporting frame SF is erected vertically may be further offset. That is, for example, the restoring force may prevent or mitigate the sagging of the first frame part F1.

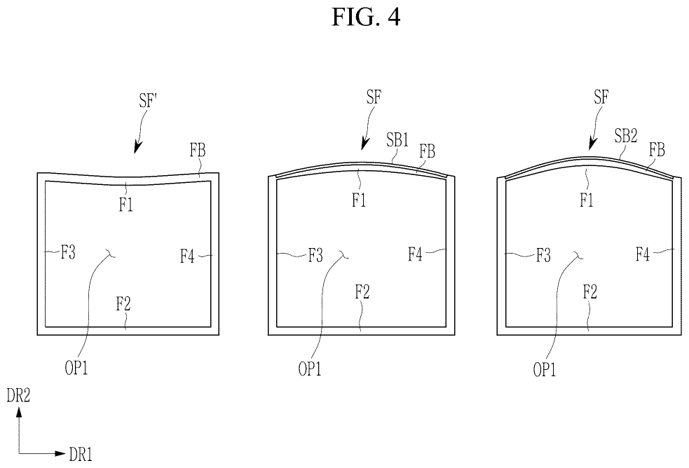

With reference to FIG. 4, the effect of the supporting frame SF according to various embodiments will be described in comparison with a supporting frame SF according to a comparative example.

FIG. 4 is a drawing to compare the supporting frame according to various embodiments with the supporting frame according to the comparative example. FIG. 4 may show that the supporting frame SF according to the embodiments and the supporting frame SF according to the comparative example stand vertically on the support surface. In FIG. 4, the first direction DR1 may be parallel to the support surface, and the second direction DR2 may be a direction perpendicular to the support surface. The second direction DR2 may be a direction perpendicular to the first direction DR1. The first supporting bar SB1 and the second supporting bar SB2 of FIG. 4 may correspond to or include like aspects of the first supporting bar SB1 and the second supporting bar SB2 of FIG. 3. Repeated descriptions of like elements are omitted for brevity.

The supporting frame SF according to the comparative example may include a body part FB and be a structure in which the body part FB is integrally formed. The body part FB may include a first frame part F1 and a second frame part F2 extending in the first direction DR1, and a third frame part F3 and a fourth frame part F4 extending in the second direction DR2. In an example in which the supporting frame SF is erected vertically on the supporting surface, the second frame part F2 may be in contact with the supporting surface, and the first frame part F1 may be disposed above the first opening OP1. The first frame part F1 may be spaced apart from the support surface by the first opening OP1. According to the comparative example, the middle part of the first frame part F1 may sag due to self-weight (e.g., weight of the middle part, weight of the first frame part F1). In FIG. 4, the direction in which the first frame part F1 sags may be the direction in which the second frame part F1 sags.

According to an embodiment, the supporting frame SF may include the body part FB and the first supporting bar SB1, and may have a structure in which the first supporting bar SB1 is coupled to the first frame part F1. The first supporting bar SB1 may be inserted and coupled to the groove formed in the first frame part F1. The first supporting bar SB1 may have a convex shape toward the outside of the supporting frame SF.

According to an embodiment, the first supporting bar SB1 may include a material with a larger thermal expansion coefficient than the material of the body part FB. The first supporting bar SB1, which includes the material with the relatively large thermal expansion coefficient, may be thermally distorted along the shape of the first supporting bar SB1, and the first supporting bar SB1 may be thermally distorted outside the supporting frame SF. In FIG. 4, the thermal distortion direction of the first supporting bar SB1 may be a direction rising in the second direction DR2.

According to an embodiment, the deflection of the first frame part F1 to which the first supporting bar SB1 is combined may be offset by the thermal distortion of the first supporting bar SB1.

According to an embodiment, the first supporting bar SB1 may include a material lighter than the material of the body part FB. According to an embodiment, the part of the first frame part F1 of the comparative example may be replaced with the first supporting bar SB including a material lighter than the first frame part F1. According to an embodiment, compared to the comparative example, when the supporting frame SF is erected vertically on the support surface, the self-weight of the part disposed on the upper side of the first opening OP1 may be reduced. According to the comparative example, the amount of the sagging due to the self-weight of the first supporting bar SB1 and the first frame part F1 according to an embodiment may be less than the amount of the sagging due to the self-weight of the first frame part F1.

According to various embodiments, the supporting frame SF may include the body part FB and the second supporting bar SB2, and may have a structure in which the second supporting bar SB2 is coupled to the first frame part F1. The second supporting bar SB2 may be inserted into the groove formed in the first frame part F1 and may be joined to the first frame part F1. The second supporting bar SB2 may have a convex shape toward the outside of the supporting frame SF, and the curvature of the second supporting bar SB2 may be smaller than the curvature of the first supporting bar SB1. According to an embodiment, the second supporting bar SB2 may be combined with the first frame part F1 after a prestress is applied to the first supporting bar SB1 in a direction that reduces the curvature.

Descriptions herein that an element may be inserted into another element may be referred to as the element being insertable into the other element. Descriptions herein that an element may be joined to another element may be referred to as the element being joinable or couplable to the other element.

According to an embodiment, the second supporting bar SB2 may have a restoring force supportive of restoring the second supporting bar SB2 according to the curvature of the first supporting bar SB1. In other words, the direction of the restoring force may be a direction in which the curvature of the second supporting bar SB2 increases. In FIG. 4, the direction in which the curvature of the second supporting bar SB2 increases may be a direction rising in the second direction DR2. According to an embodiment, the sagging phenomenon of the first frame part F1 to which the second supporting bar SB2 is combined may be offset by the restoring force of the prestressed second supporting bar SB2.

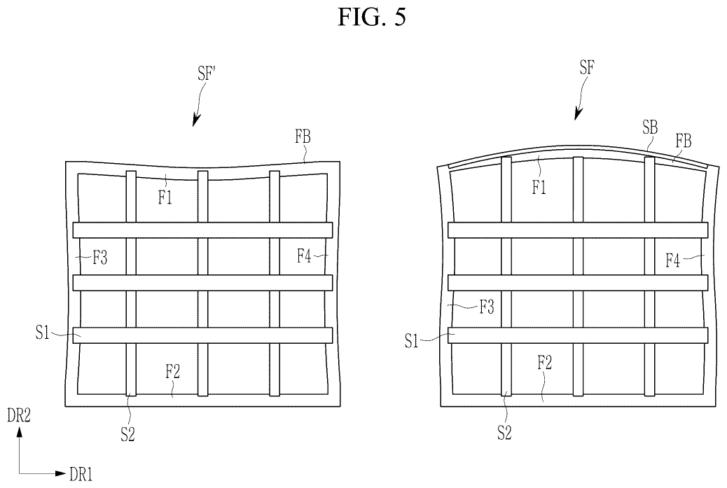

With reference to FIG. 5, the effect of the supporting frame SF according to an embodiment will be described compared with a supporting frame SF according to a comparative example.

FIG. 5 is a view to compare a supporting frame according to an embodiment with a supporting frame according to a comparative example. FIG. 5 may indicate a state in which the supporting frame SF according to an embodiment and the supporting frame SF according to the comparative example are erected vertically on the support surface. In FIG. 5, the first direction DR1 may be parallel to the support surface, and the second direction DR2 may be a direction perpendicular to the support surface. The second direction DR2 may be a direction perpendicular to the first direction DR1.

The supporting frame SF according to the comparative example in FIG. 5 may correspond to the supporting frame SF according to the comparative example in FIG. 4. According to the comparative example, the first stick S1 and the second stick S2 may be coupled to the body part FB of the supporting frame SF. The first stick S1 may extend in the first direction DR1, and both ends of the first stick S1 may be coupled to the third frame part F3 and the fourth frame part F4, which are spaced apart in the first direction DR1, respectively. The second stick S2 may extend in the second direction DR2, and both ends of the second stick S2 may be coupled to the first frame part F1 and the second frame part F2, respectively, which are spaced apart in the second direction DR2. The first stick S1 and the second stick S2 may be pulled in the length direction and coupled to the supporting frame SF′. The compressive force may act on the supporting frame SF′ in each tensile direction of the first stick S1 and the second stick S2. The compressive force caused by the second stick S2 may be applied to the first frame part F1 and the second frame part F2. The compressive force caused by the first stick S1 may act on the third frame part F3 and the fourth frame part F4. The direction of the compressive force may be the inner direction of the supporting frame SF′.

According to the comparative example, in the first frame part F1, the compressive force caused by the second stick S2 and a gravitational force may act in the same direction. In FIG. 5, the direction of the compressive force and the gravitational force by the second stick S2 may be the descending direction of the second direction DR2. The first frame part F1 can sag in the descending direction of the second direction DR2.

According to an embodiment, the first stick S1 and the second stick S2 may be coupled to the body part FB of the supporting frame SF. According to an embodiment, the supporting bar SB may be coupled to the first frame part F1 of the supporting frame SF. The supporting bar SB of FIG. 5 may correspond to or include like aspects of the first supporting bar SB1 or the second supporting bar SB2 of FIG. 4. Repeated descriptions of like elements are omitted for brevity. The supporting bar SB may have a shape convex toward the outside of the supporting frame SF. As the temperature increases, thermal distortion may occur in the supporting bar SB to the outside of the supporting frame SF based on the shape of the supporting bar SB. The thermal distortion direction of the supporting bar SB may be the rising direction of the second direction DR2.

As described herein, the direction of the compressive force and the gravitational force by the second stick S2 is the descending direction of the second direction DR2, so the first frame part F1 may sag in the descending direction of the second direction DR2. According to an embodiment, in the first frame part F1 of the supporting frame SF, the compressive force caused by the second stick S2 and the gravitational force (gravity) may act in a direction opposite to the thermal distortion direction of the supporting bar SB. Due to the thermal distortion of the supporting bar SB, the deflection of the first frame part F1 to which the supporting bar SB is coupled may be offset.

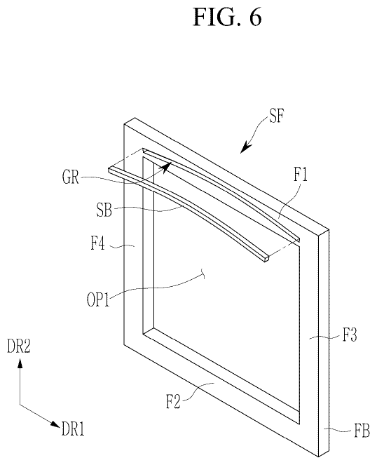

Hereinafter, various supporting frames according to an embodiment are described with reference to FIG. 6 to FIG. 8.

FIG. 6 to FIG. 8 are exploded perspective views of a supporting frame according to an embodiment. Hereinafter, the explanation will focus on the differences from the supporting frame SF according to an embodiment of FIG. 1 and FIG. 2, and any overlapping content will be omitted or simplified.

Referring to FIG. 6, according to an embodiment, a supporting frame SF may include a body part FB and a supporting bar SB coupled to the body part FB.

The body part FB may include a first frame part F1 and a second frame part F2 extending in a first direction DR1, and a third frame part F3 and a fourth frame part F4 extending in second direction DR2 vertical to the first direction DR1. The first frame part F1, the second frame part F2, the third frame part F3, and the fourth frame part F4 may surround the first opening OP1.

According to an embodiment, the body part FB may have a square ring shape, but embodiments of the present disclosure are not limited thereto. The body part FB may include a front surface and a rear surface facing in a direction in which the first opening OP1 penetrates the supporting frame. The direction through which the first opening OP1 penetrates the supporting frame may be a direction perpendicular to the first direction DR1 and the second direction DR2. For example, FIG. 6 may show the rear surface of the body part FB, but embodiments of the present disclosure are not limited thereto. A groove where the stick (the first stick S1 and the second stick S2 in FIG. 1) is joined may be formed on the front surface of the body part FB, not illustrated, but embodiments of the present disclosure are not limited thereto.

According to an embodiment, the rear surface of the first frame part F1 may include a groove GR that is recessed toward the front surface of the first frame part F1. The groove GR may have a shape extending in the first direction DR1. The groove GR may have a depth in a direction perpendicular to the first direction DR1 and the second direction DR2. The depth of the groove GR may be smaller than the thickness of the first frame part F1 (the length according to the direction vertical to the first direction DR1 and the second direction), but embodiments of the present disclosure are not limited thereto. For example, the groove GR may penetrate the first frame part F1 in a direction perpendicular to the first direction DR1 and the second direction. In this case, for example, the depth of the groove GR may be equal to the thickness of the first frame part F1 (the length according to the direction perpendicular to the first direction DR1 and the second direction).

According to an embodiment, the bottom surface of the groove GR may be parallel and flush with the front surface and the rear surface of the first frame part F1. The inner surface of the groove GR may be composed of four sides. The inner surface of the groove GR may include a first side and a second side facing in the first direction DR1, and a third side and a fourth side facing in the second direction DR2.

According to an embodiment, the groove GR may have a shape convex toward the outside of the supporting frame SF. The cross-section shape according to the first direction DR1 and the second direction DR2 of the groove GR may be convex toward the outside of the supporting frame SF. Among the inner surfaces of the groove GR, the third side and the fourth side facing in the second direction DR2 may be convex toward the outside of the supporting frame SF. In FIG. 6, the third side and the fourth side may be convex in the rising direction of the second direction DR2.

The supporting bar SB may be coupled to the first frame part F1 disposed on the upper side of the first opening OP1 when the supporting frame SF is erected vertically. According to an embodiment, the supporting bar SB may be inserted into the groove GR formed on the rear surface of the first frame part F1 in a direction vertical to the first direction DR1 and the second direction DR2. The supporting bar SB may have a shape corresponding to the groove GR of the first frame part F1. According to an embodiment, the supporting bar SB extends in the first direction DR1, and the cross-section shape according to the first direction DR1 and the second direction DR2 may be convex toward the outside of the supporting frame SF.

According to an embodiment, the material of the supporting bar SB may have a larger thermal expansion coefficient than the material of the body part FB. In the supporting bar SB, which includes a material with a larger thermal expansion coefficient than the body part FB, thermal distortion may occur along the shape of the supporting bar SB as the temperature increases. The thermal distortion direction of the supporting bar SB may be opposite to the direction of the gravitational force (gravity) acting on the first frame part F1 when the supporting frame SF is erected vertically and/or the compressive force caused by the stick (e.g. the second stick S2 in FIG. 1) acting on the first frame part F1. Therefore, the amount of the deflection of the first frame part F1 may be reduced due to the thermal distortion of the supporting bar SB.

According to an embodiment, the material of the supporting bar SB may weigh less than (i.e., may be lighter than) the material of the body part FB. As the supporting bar SB inserted into the first frame part F1 includes a lighter material than the body part FB, the amount of gravitational force (due to gravity) acting on the first frame part F1 may be reduced, and the amount of the deflection of the first frame part F1 may be reduced.

According to an embodiment, the supporting bar SB may be subjected to the prestress before being coupled to the first frame part F1. Due to the prestress, the supporting bar SB may be coupled to the first frame part F1 with a smaller curvature compared to the initial shape. The restoring force of the supporting bar SB may attempt to restore (or partially restore) the supporting bar SB to the initial shape of the supporting bar SB in a state in which the supporting bar SB is coupled to the first frame part F1. The restoring force in the direction of increasing the curvature may be applied to the supporting bar SB. The direction of the restoring force of the supporting bar SB may be opposite to the direction in which the first frame part F1 sags. Since the supporting bar SB is coupled to the first frame part F1, the restoring force acting on the supporting bar SB may also act on the first frame part F1. The amount of the deflection of the first frame part F1 may be further reduced by the restoring force of the supporting bar SB.

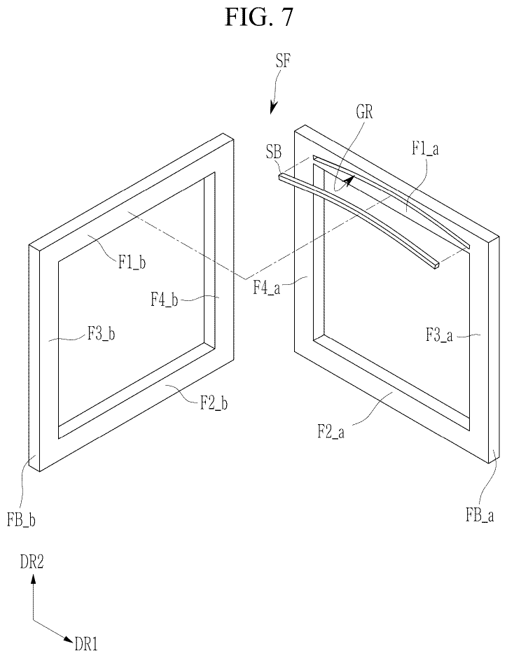

Hereinafter, for the supporting frame SF according to an embodiment of FIG. 7, the explanation will focus on the differences from the supporting frame SF according to an embodiment in FIG. 6, and overlapping content will be omitted or simplified.

Referring to FIG. 7, according to an embodiment, the body part FB of the supporting frame SF may include a first body part FB_a and a second body part FB_b. The first body part FB_a may include a first frame part F1_a, a second frame part F2_a, a third frame part F3_a, and a fourth frame part F4_a. The second body part FB_b may include a first frame part F1_b, a second frame part F2_b, a third frame part F3_b, and a fourth frame part F4_b.

The first frame part F1_a of the first body part FB_a and the first frame part F1_b of the second body part FB_b may be joined together. The second frame part F2_a of the first body part FB_a and the second frame part F2_b of the second body part FB_b may be joined together. The third frame part F3_a of the first body part FB_a and the third frame part F3_b of the second body part FB_b may be joined together. The fourth frame part F4_a of the first body part FB_a and the fourth frame part F4_b of the second body part FB_b may be joined together. The first surface of the first body part FB_a and the second surface of the second body part FB_b may be joined together.

According to an embodiment, the first surface of the first frame part F1_a of the first body part FB_a may include a groove GR that is recessed toward the opposite side of the first surface. For the shape and structure of the groove GR, the description of the groove GR in FIG. 6 may be applied equally.

The supporting bar SB may be coupled to the first frame part F1_a of the first body part FB_a. According to an embodiment, the supporting bar SB may be inserted into the groove GR formed on the first surface of the first frame part F1_a in a direction vertical to the first direction DR1 and the second direction DR2. The supporting bar SB may have a shape corresponding to the groove GR of the first frame part F1_a.

According to an embodiment, the entrance of the groove GR may be blocked by the second surface of the first frame part F1_b of the second body part FB_b. The supporting bar SB may be completely surrounded by the first body part FB_a and the second body part FB_b.

The supporting frame SF according to an embodiment of FIG. 7 may have the same effect of the supporting frame SF according to an embodiment of FIG. 6.

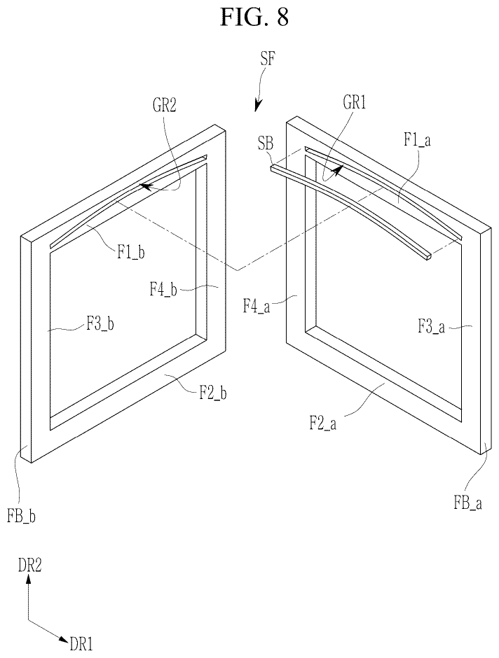

Hereinafter, regarding the supporting frame SF according to an embodiment of FIG. 8, the explanation will focus on the differences from the supporting frame SF according to an embodiment in FIG. 7, and overlapping content will be omitted or simplified.

Referring to FIG. 8, according to an embodiment, the body part FB of the supporting frame SF may include a first body part FB_a and a second body part FB_b. The first surface of the first body part FB_a and the second surface of the second body part FB_b may be joined together.

According to an embodiment, the first surface of the first frame part F1_a of the first body part FB_a may include a first groove GR1 that is recessed toward the opposite side of the first surface. The second surface of the first frame part F1_b of the second body part FB_b may include a second groove GR2 that is recessed toward the opposite side of the second surface. For the shape and structure of the first groove GR1 and the second groove GR2, the description of the groove GR in FIG. 6 may be applied equally.

The supporting bar SB may be coupled to the first frame part F1_a of the first body part FB_a and the first frame part F1_b of the second body part FB_b. According to an embodiment, the supporting bar SB may be inserted into the first groove GR1 formed on the first surface of the first frame part F1_a and the second groove GR2 formed on the second surface of the first frame part F1_b in a direction perpendicular to the first direction DR1 and the second direction DR2. A part (i.e., a portion) of the supporting bar SB may be inserted into the first groove GR1, and the remaining part (i.e., remaining portion) may be inserted into the second groove GR2. The supporting bar SB may have a shape corresponding to the groove where the first groove GR1 and the second groove GR2 are joined together.

According to an embodiment, the entrance of the first groove GR1 may be blocked by the second surface of the first frame part F1_b) of the second body part FB_b. The entrance of the second groove GR2 may be blocked by the first surface of the first frame part F1_a of the first body part FB_a. The supporting bar SB may be completely surrounded by the first body part FB_a and the second body part FB_b.

The supporting frame SF according to an embodiment of FIG. 8 may have the same effect as the supporting frame SF according to an embodiment of FIG. 7.

While this disclosure has been described in connection with what is presently considered to be practical example embodiments, it is to be understood that the disclosure is not limited to the disclosed embodiments, but, on the contrary, is intended to cover various modifications and equivalent arrangements included within the spirit and scope of the appended claims.

What is claimed is:

1. A supporting frame comprising:
a body part comprising a first frame part, a second frame part, a third frame part, and a fourth frame part disposed on a first side, a second side, a third side, and a fourth side of an opening, respectively, and
a supporting bar coupled to the first frame part,
wherein the supporting bar has a shape convex toward an outside of the supporting frame.

2. The supporting frame of claim 1, wherein:
in a state in which the supporting frame is erected vertically, the first frame part is positioned on an upper side of the opening.

3. The supporting frame of claim 1, wherein:
the supporting bar is formed such that the supporting bar has a first curvature, and
the supporting bar is transformable and joinable to the first frame part based on an external force, wherein in response to the external force, the supporting bar has a second curvature less than the first curvature and is joined to the first frame part.

4. The supporting frame of claim 1, wherein:
the body part comprises a first material,
the supporting bar comprises a second material, and
a thermal expansion coefficient of the second material is larger than a thermal expansion coefficient of the first material.

5. The supporting frame of claim 4, wherein:
the second material weighs less than the first material.

6. The supporting frame of claim 1, wherein:
an outer surface of the first frame part comprises a groove that is recessed toward an inner surface of the first frame part,
a bottom surface of the groove is convex toward an outside of the supporting frame, and
the supporting bar is inserted into the groove.

7. The supporting frame of claim 6, wherein:
the outer surface of the first frame part and the inner surface of the supporting bar each comprise alternating protrusions and depressions, and
the protrusions of the outer surface of the first frame part are configured to interlock with the depressions of the inner surface of the supporting bar, and the depressions of the outer surface of the first frame part are configured to interlock with the protrusions of the inner surface of the supporting bar.

8. The supporting frame of claim 1, wherein:
the body part comprises a front surface and a rear surface facing in a direction where the opening penetrates the supporting frame,
a rear surface of the first frame part comprises a groove that is recessed toward a front surface of the first frame part, wherein the groove has a shape convex toward the outside of the supporting frame, and
the supporting bar is inserted into the groove.

9. The supporting frame of claim 1, wherein:
the body part comprises a first body part and a second body part that are joined in a thickness direction of the supporting frame,
the first body part and the second body part each comprise a respective first frame part, a respective second frame part, a respective third frame part, and a respective fourth frame part;
a first surface of the first frame part of the first body part, which is joined to the first frame part of the second body part, comprises a groove recessed toward an opposite side of the first surface, and the groove has a shape that is convex toward the outside of the supporting frame, and
the supporting bar is inserted into the groove, and an entrance of the groove is blocked by a second surface of the first frame part of the second body part, which is joined to the first frame part of the first body part.

10. The supporting frame of claim 9, wherein:
the first surface of the first frame part of the first body part comprises a first groove that is recessed toward the opposite side of the first surface,
the second surface of the first frame part of the second body part comprises a second groove recessed toward the opposite side of the second surface,
the first groove and the second groove each have a shape convex toward the outside of the supporting frame,
a part of the supporting bar is inserted into the first groove, and
a remaining part of the supporting bar is inserted into the second groove.

11. A mask assembly comprising:
a supporting frame comprising:
a body part surrounding a first opening; and
a supporting bar coupled to the body part,
a first stick disposed on the supporting frame and extending in a first direction,
a second stick disposed on the supporting frame and extending in a second direction perpendicular to the first direction, and
a unit mask disposed on the supporting frame, the first stick, and the second stick, and comprising one or more second openings,
wherein:
the body part comprises a first frame part, a second frame part, a third frame part, and a fourth frame part disposed on a first side, a second side, a third side, and a fourth side of the first opening, respectively,
the supporting bar is coupled to the first frame part, and
the supporting bar has a shape convex toward an outside of the supporting frame.

12. The mask assembly of claim 11, wherein:
in a state in which the supporting frame is erected vertically, the first frame part is positioned on an upper side of the first opening.

13. The mask assembly of claim 11, wherein:
the supporting bar is formed such that the supporting bar has a first curvature, and
the supporting bar is transformable and joinable to the first frame part based on an external force, wherein in response to the external force, the supporting bar has a second curvature less than the first curvature and is joined to the first frame part.

14. The mask assembly of claim 11, wherein:
the body part comprises a first material,
the supporting bar comprises a second material, and
a thermal expansion coefficient of the second material is larger than a thermal expansion coefficient of the first material.

15. The mask assembly of claim 14, wherein:
the second material weighs less than the first material.

16. The mask assembly of claim 11, wherein:
an outer surface of the first frame part comprises a groove that is recessed toward an inner surface of the first frame part,
a bottom surface of the groove is convex toward an outside of the supporting frame, and
the supporting bar is inserted into the groove.

17. The mask assembly of claim 16, wherein:
the outer surface of the first frame part and the inner surface of the supporting bar each comprise alternating protrusions and depressions, and
the protrusions of the outer surface of the first frame part are configured to interlock with the depressions of the inner surface of the supporting bar, and the depressions of the outer surface of the first frame part are configured to interlock with the protrusions of the inner surface of the supporting bar.

18. The mask assembly of claim 11, wherein:
the body part comprises a front surface to which the unit mask is affixed and a rear surface opposite to the front surface,
a rear surface of the first frame part comprises a groove that is recessed toward a front surface of the first frame part, wherein the groove has a shape convex toward the outside of the supporting frame, and
the supporting bar is inserted into the groove.

19. The mask assembly of claim 11, wherein:
the body part comprises a first body part and a second body part that are joined in a thickness direction of the supporting frame,
the first body part and the second body part each comprise a respective first frame part, a respective second frame part, a respective third frame part, and a respective fourth frame part,
a first surface of the first frame part of the first body part, which is joined to the first frame part of the second body part, comprises a groove recessed toward an opposite side of the first surface, and the groove has a shape that is convex toward the outside of the supporting frame, and
the supporting bar is inserted into the groove, and an entrance of the groove is blocked by a second surface of the first frame part of the second body part, which is joined to the first frame part of the first body part.

20. The mask assembly of claim 19, wherein:
the first surface of the first frame part of the first body part comprises a first groove that is recessed toward the opposite side of the first surface,
the second surface of the first frame part of the second body part comprises a second groove recessed toward the opposite side of the second surface,
the first groove and the second groove each have a shape convex toward the outside of the supporting frame,
a part of the supporting bar is inserted into the first groove,
and a remaining part of the supporting bar is inserted into the second groove.
